(19) United States
(12) Patent Application Publication
(10) Pub. No.: US 2017/0113297 A1
(43) Pub. Date: Apr. 27, 2017

(54) METALLIZING POLYMERS, CERAMICS AND COMPOSITES FOR ATTACHMENT STRUCTURES

(71) Applicant: Hutchinson Technology Incorporated, Hutchinson, MN (US)

(72) Inventors: Michael W. Davis, Rockford, MN (US); Douglas P. Riemer, Waconia, MN (US); Clark T. Olsen, Dassel, MN (US); Steven R. Lagergren, Litchfield, MN (US); Paul V. Pesavento, Hutchinson, MN (US)

(21) Appl. No.: 15/334,986

(22) Filed: Oct. 26, 2016

Related U.S. Application Data
(60) Provisional application No. 62/246,909, filed on Oct. 27, 2015.
(60) Provisional application No. 62/312,012, filed on Mar. 23, 2016.

(51) Int. Cl. B23K 20/10; B23K 1/19; B23K 20/233; B23K 20/02; C23C 14/20; C23C 18/32; C23C 14/34; C23C 14/24; C25D 3/04; C25D 7/00; C25D 5/56; C23C 18/16; B23K 1/00; C23C 14/18

(52) U.S. Cl. CPC B23K 20/10; B23K 1/0008; B23K 1/19; B23K 20/233; B23K 20/023; C23C 14/205; C23C 14/185; C23C 14/34; C23C 14/24; C25D 3/04; C25D 7/00; C25D 5/56; C23C 18/1641; C23C 18/32; B23K 2201/35

(57) ABSTRACT

A method of manufacture includes forming a metallized tie layer on a surface of a non-metallic component, positioning the surface of the non-metallic component to mate with a metallic surface of a second component, and joining the metallized tie layer with the mated metallic surface of the second component using metal to metal joining techniques.

### CROSS-REFERENCE TO RELATED APPLICATIONS

This application claims priority to U.S. Provisional Application No. 62/246,909, filed Oct. 27, 2015, and U.S. Provisional Application 62/312,012, filed Mar. 23, 2016. The entire contents of both of these applications are incorporated by reference herein for all purposes.

### TECHNICAL FIELD

This disclosure relates generally to techniques for joining polymeric, ceramic, or ceramic-polymer composite components to another component.

### BACKGROUND

In overmolding to create structural attachment between a polymeric, ceramic, or ceramic-polymer composite component and underlying component(s) within an assembly, it may be difficult to obtain an adequate bond. This is exacerbated when the overall assembly size is preferably as small as possible, since the overmold requires adding to the volume of the assembly. Overmolded component surfaces may have limited or no adhesion to the surfaces of the underlying component. This lack of adhesion between mating surfaces of an assembly including an overmolded component may limit the strength of the assembly compared to alternatives in which adjacent surfaces of components within an assembly are adhered to each other.

### DETAILED DESCRIPTION

Manufacture techniques disclosed herein facilitate attachment surfaces on a non-metallic component, such as a polymeric (e.g., plastic), ceramic, or ceramic-polymer composite component for attaching the non-metallic component to a metal component, or another non-metallic component. As one example, surfaces to be joined are metallized to provide a ‘tie’ layer so that alternative bonding methods can be used. For polymeric and ceramic components, the metallized layers can be created with sputtering, such as sputtering with chromium and or copper. For metal components, sputtering or plating, such as nickel plating, can be used if needed to provide a metallized ‘tie’ layer suitable for joining. The metallized ‘tie’ layers can be joined with a variety of methods, including, for example, soldering, brazing, adhesive bonding (using an adhesive designed for metal to metal bonding), metal fusion bonding, such as gold fusion bonding, and other metal to metal joining techniques. The techniques disclosed herein may be particularly useful for joining plastic to plastic, ceramic to ceramic, ceramic to metal, ceramic to plastic and/or plastic to metal components for products exposed to harsh environments, such as medical applications.

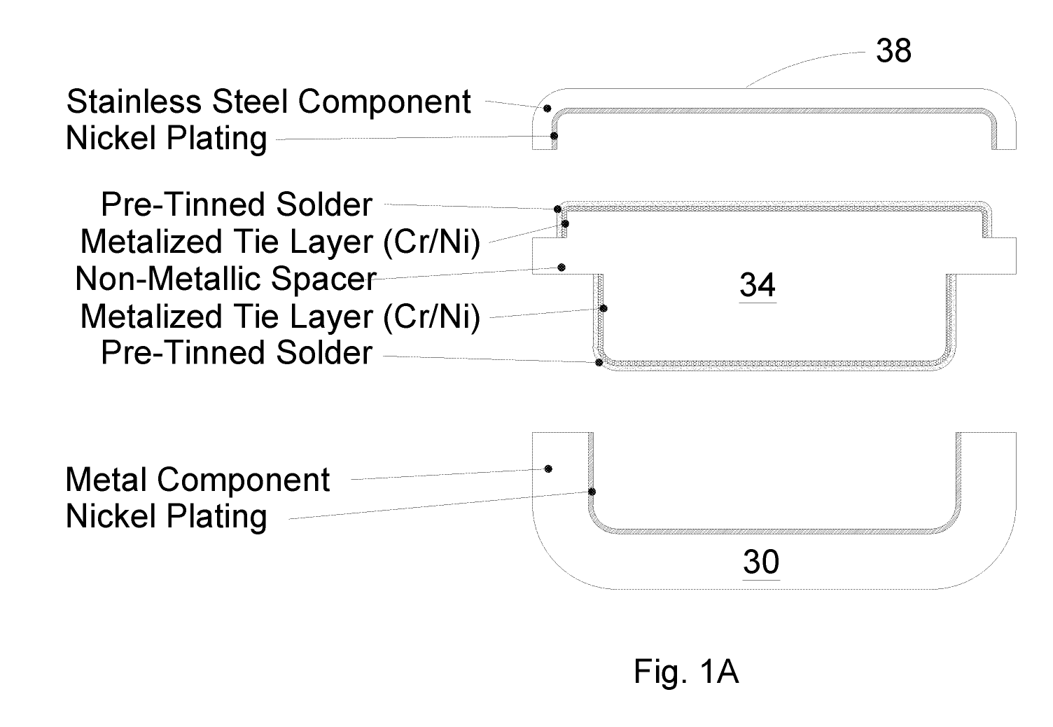

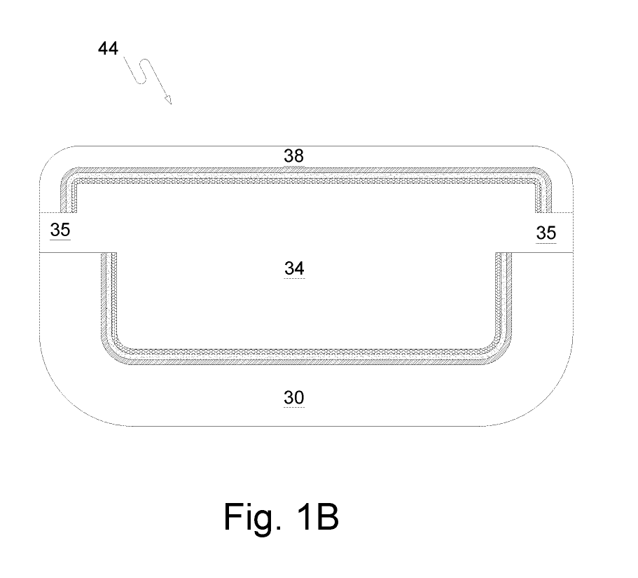

When joining surfaces of components with at least one polymeric or ceramic surface, such as non-metallic spacer 34 of assembly 44 (FIG. 1B), bonding directly to the polymeric or ceramic surface may result in poor adhesion. As disclosed herein, first applying a metallized tie layer to the polymeric or ceramic surface provides a different functional surface for an adhesive to bond to. In the case of bonding two polymeric or ceramic components together, both components may be selectively sputtered with a metallized tie layer so that a metal-to-metal adhesive may be applied to join the surfaces. Such metal-to-metal adhesive may provide good bonding to the metallized tie layers and provide improved adhesion as compared to conventional techniques for polymer to polymer, ceramic to ceramic, ceramic to plastic, ceramic to metal and/or plastic to metal bonding.

These techniques may facilitate attaching a formed (planer or non-planar) metal component to a non-metallic component, such as a support structure, spacer or stand-off, although it could also be used to bond two non-metallic components. The non-metallic component can alternatively be formed using other known methods for example, stamping, laser cutting, machining, and extruding.

In the example of two non-metallic components, the described surface preparation techniques may be applied to both of the non-metallic surfaces being attached and bonded. For plastic to plastic, ceramic to ceramic or ceramic to plastic surface joining, metalized surfaces may be formed on both non-metallic components to act as a different surface onto which the bond can occur. Bonding may occur by solder, brazing, Au bonding, adhesives, or other metal to metal bonding techniques.

Certain ceramics, ceramic-polymer composites and plastic resins in the polyamide family such as Zytel, Akromid, Amodel, and similar are difficult to bond to metals including bonding with adhesives. Difficulties in such bonding may occur when the surface is non-planer or has 3D curved surfaces that mate. The techniques disclosed herein may be particularly useful for bonding such ceramics, ceramic-polymer composites and plastic resins to metal, ceramic or polymeric components.

FIGS. 1A-1B illustrate components of an assembly 44. FIGS. 1A-1B illustrate an assembly technique utilizing solder as the attachment method between the tie layers. In particular, FIG. 1A illustrates an exploded view of the components of assembly 44, whereas FIG. 1B illustrates a cross-sectional view of the attached components of assembly 44.

Assembly 44 includes metal component 30, non-metallic spacer 34 and stainless steel component 38. As shown in FIG. 1B, metal component 30 and stainless steel component 38 include optional nickel plating layers on surface to be joined with non-metallic spacer 34. Likewise, non-metallic spacer 34 includes metalized tie layer, such as a chromium, copper, and/or nickel layer, as well as a solder layer that can be pre-tinned or applied using other known methods, on the surfaces to be joined with metal component 30 and stainless steel component 38. Such solder may be a solder suitable for use on medical devices, such as Indalloy 121 (or similar). In alternative examples, in which adhesive joining the metallized surfaces is chosen in place of solder, then the solder layer is not needed. Stainless steel component 38 may include a plating layer, such as a nickel plating layer.

Prior to metal-to-metal bonding techniques to bond metal component 30, non-metallic spacer 34 and stainless steel component 38 together, the components should be properly aligned as desired for the final assembly. For solder attach bonding, the components may be stacked and aligned and baked to allow the pre-tinned low temp solder to reflow and wet to the metallized portions of the mating pieces. Generally, the solder should wet only to the metallized regions.

In glue attach bonding, (metallized to metallized), adhesive may be applied before stacking and aligning the components. The metallized faces provide an alternative to bonding directly to non-metallic spacer 34 and may provide stronger adhesion that directly applying an adhesive to non-metallic spacer 34.

As shown in FIG. 1B, metal component 30, non-metallic spacer 34 and stainless steel component 38 may be joined by way metal-to-metal bonding techniques, such as solder or other techniques. In this manner, an overmold layer is not needed. The interface surfaces for a strong mechanical attachment provided by the metalized tie layer on non-metallic spacer 34 allows non-metallic spacer 34 to be joined using metal joining techniques to other components, such as metal component 30 and stainless steel component 38. These techniques eliminate the need for an overmold.

Assembly 44 provides sealing between metal component 30, non-metallic spacer 34 and stainless steel component 38. For this reason, in a bending type loading applied to assembly 44, the three layers, i.e., metal component 30, non-metallic spacer 34 and stainless steel component 38, reinforce each other to provide additional bending strength than with what may be achieved with conventional overmolding.

In some particular examples, assembly 44 may represent components within a medical instrument. In such examples, it may be important to electrically and/or thermally isolate stainless steel component 38 from metal component 30. In some such examples, the thickness of stainless steel component 38 may be about 0.010 inches. In the same or different examples, the thickness of metal component 30 may be about 0.025 inches. Attachment surfaces of metal component 30 and stainless steel component 38 may be optionally nickel plated, chrome plated or plated with other materials to provide the proper tie layer interface. In addition, adjacent surfaces of non-metallic spacer 34 may be metalized with a tie layer to facilitate bonding to metal component 30 and stainless steel component 38 using metal-to-metal joining techniques. Such metalized tie layers are optionally patterned. In some examples, non-metallic spacer 34 may be a polymeric component, such as an injection molded fiber filled component, such as glass fiber or carbon fiber component, a ceramic component, or a blend of polymer and ceramic materials forming a composite component.

In a variation of assembly 44, a high strength non-metallic may be added instead of or in addition to metal component 30 in order to provide structural strength to the assembly. In another variation, the function of metal component 30 and non-metallic spacer 34 may be replaced by a single high strength non-metallic component layer.

In a further variation of assembly 44, stainless steel component 38 may be replaced with an electroplated component on non-metallic spacer 34 or directly on a high strength non-metallic component layer. Such electroplating and/or electroforming may occur on a metalized tie layer of the non-metallic component.

Following the formation of a metalized tie layer on the non-metallic component, the surface of the non-metallic component may be positioned to mate with a metallic surface of a second component. Then the metallized tie layer on the non-metallic component may be joined with the mated metallic surface of the second component using metal to metal joining techniques.

The second component may be a metal component or a non-metallic component with a second metallized tie layer on the second component. In different examples, metallized tie layers may be used for joining plastic to plastic, ceramic to ceramic, ceramic to metal, ceramic to plastic and/or plastic to metal components for products exposed to harsh environments, such as medical applications.

In accordance with the techniques disclosed herein, possible methods of metal-to-metal attachment of one or more non-metallic components include, fusion of metal (welding), brazing, soldering, adhesive bonding, fusion of plated metals (e.g., via ultrasonics or resistance), or other metal-to-metal bonding techniques as discussed in further detail below.

As the properties of certain base materials, such as metallic components and metallic components may be affected at temperatures required for particular bonding techniques, metal-to-metal bonding techniques that do not require temperatures adverse to the base materials. Generally speaking, bonding techniques rely on materially-compatible (wettable and having an ability to form a strong bond after wetting and cooling/solidification), pre-prepared substrate and bonding part surfaces that can readily adhere/bond to the molten metal bonding material.

In addition to the techniques listed above, low temperature melting nanoparticle material bonding techniques may be useful in some examples for joining plastic to plastic, ceramic to ceramic, ceramic to metal, ceramic to plastic and/or plastic to metal components. With low temperature melting nanoparticle material bonding a “nanoparticle” solder that achieves lower processing temperatures by using small particle sizes to fully melt the solder at temperatures the base material of component can handle.

As another example, low temperature and pressure sintering bonding techniques may be useful in some examples for joining plastic to plastic, ceramic to ceramic, ceramic to metal, ceramic to plastic and/or plastic to metal components. With low temperature and pressure sintering bonding sintering mostly relies on partially melting a bonding material (such as softening/melting the surface of the particles to be sintered) and then applying pressure to form the high surface area strong bond with the components. Such techniques may use a low-temperature “nanoparticle” solder or other sintering materials.

As other examples, melting or reactive photonic curing or sintering bonding may be useful in some examples for joining plastic to plastic, ceramic to ceramic, ceramic to metal, ceramic to plastic and/or plastic to metal components. With melting or reactive photonic curing or sintering bonding a “flashlamp melted” material may allow for maintaining low temperatures through ultra-fast heating and melting of the bonding material. The bonding material may absorb the flashlamp energy and simply melt or the bonding material may starts an exothermic, self-sustaining reaction at the surface which may propagate across and through the film such that the film which melts itself and wets and heats the surface of components to form a bond.

As other examples, low temperature and pressure reactive soldering/brazing material bonding may be useful in some examples for joining plastic to plastic, ceramic to ceramic, ceramic to metal, ceramic to plastic and/or plastic to metal components. With low temperature and pressure reactive soldering/brazing material bonding a molten compound formation, typically a eutectic compound, may be located between the metal bonding material and the substrate and component. Such techniques are distinct than those in which rely upon a melting of only the bonding material which then wets to the components. The molten material for low temperature and pressure reactive soldering/brazing material bonding can be formed through the application of heat and pressure to get interdiffusion and start the eutectic compound formation, which then melts at the current temp. Alternatively or additionally, the molten material for low temperature and pressure reactive soldering/brazing material bonding can be formed by using multiple-component (mixtures of particles or multilayer films) bonding materials such that they melt and intermix due to an ignition event (such as an electric arc or laser heating at one tiny spot), then, due to high energy of mixing and self-propagating reaction, the entire bonding material melts and gives off enormous amounts of heat, which causes strong bond formation to the substrate and bonding part while maintaining low average/equilibrium temperature and minimizing the thermal effect on substrates.

Alternatives to non-conductive spacer concepts include:
Use of high performance board as the non-conductive spacer. (Such as but not limited to Rogers LoPro RO4000 series high frequency laminates, available from Rogers Corporation of Rogers, Conn., United States). This could be utilized as a laminate (IE—pre clad with conductive layers), and/or it could be an unclad core which is subsequently metallized by techniques discussed above.
Use of powder coating as the non-conductive spacer.

### EXAMPLES

Variations of processing options for joining a non-metallic surface to a metal surface, such as a joining a non-metallic surface non-planar (3D) metal surface, as shown in FIG. 1B, are described below. These examples are merely representative of the techniques disclosed herein and other techniques may be used within the spirit of this disclosure.

### Example A

A non-metallic component, such as a plastic, ceramic or plastic ceramic composite 3D component, is modified with an oxygen containing plasma. A surface of the non-metallic component is then sputtered with Cr to form a tie layer to a subsequent solderable metal. The tie layer is from 50 angstrom to 500 angstroms thick. The tie layer is preferably 75 to 150 angstroms thick. The sputtered subsequent solderable metal is chosen from Cu, Ni, Au, Pt, Pd, etc., such as Ni, Pt, Pd. The thickness of the solderable metal may be greater than 500 angstroms and less than 50000 angstroms, such as greater than 1000 angstroms and less than 5000 angstroms.

### Example B

In this example, the techniques of Example A are repeated with the addition of compression bonding using gold as the bonding material and chrome as the tie layer.

### Example C

In this example, the techniques of Example A are repeated with mismatched metals such as nickel on one surface, Pd on another, or Au on one and nickel on the other, etc.

### Example D

In this example, the techniques of Example A are repeated where the non-metallic component is difficult to bond by adhesives such as polyamides, polytetraflourides, polydiflourides, etc.

### Example E

In this example, bonding two non-metallic components are bonded together. Mating surfaces of both components are selectively sputtered with a metallized tie layer so that a metal-to-metal joining techniques, such as a metal-to-metal adhesive may be applied to join the surfaces. Such metal-to-metal adhesive be may provide good bonding to the metallized tie layers and provide improved adhesion as compared to conventional techniques for plastic to plastic, ceramic to ceramic or ceramic to plastic bonding.

In an Example 1, a method of manufacture comprising: forming a metallized tie layer on a surface of a non-metallic component, positioning the surface of the non-metallic component to mate with a metallic surface of a second component, and joining the metallized tie layer with the mated metallic surface of the second component using metal to metal joining techniques.

In an Example 2, the method of Example 1, wherein the non-metallic component is one of a group consisting of: a polymeric component, a ceramic component, a ceramic-polymer composite component, and a resin plastic injection molded component.

In an Example 3, the method of Example 1, wherein the metal to metal joining techniques include compression fusion welding.

In an Example 4, the method of Example 3, wherein the surfaces of the non-metallic component and the metallic surface of the second component are gold plated, wherein the compression fusion welding is made by contacting the two gold plated surfaces and applying an energy source.

In an Example 5, the method of Example 4, wherein the energy source is ultrasonic or megasonic in nature.

In an Example 6, the method of Example 4, wherein the gold is held to the surface of the non-metallic component by another metal forming the metallized tie layer.

In an Example 7, the method of Example 1, wherein forming a metallized tie layer includes electroplating.

In an Example 8, the method of Example 1, wherein forming a metallized tie layer includes electroless plating.

In an Example 9, the method of Example 1, wherein forming a metallized tie layer includes vacuum deposition.

In an Example 10, the method of Example 1, wherein forming a metallized tie layer includes sputtering of a metal.

In an Example 11, the method of Example 10, wherein the sputtered metal includes one or more of Ti, Cr, Ta, Ru, NiChrome and NiV.

In an Example 12, the method of Example 10, wherein the sputtered metal is selectively deposited utilizing a shadow mask.

In an Example 13, the method of Example 1, wherein forming a metallized tie layer includes vapor deposition.

In an Example 14, the method of Example 1 further comprising modifying the surface of the non-metallic component by an ion source containing oxygen, or argon or both prior to forming the metallized tie layer on the surface of the non-metallic component.

In an Example 15, the method of Example 1 further comprising modifying the surface of the non-metallic component by an plasma source containing oxygen, or argon or both prior to forming the metallized tie layer on the surface of the non-metallic component.

In an Example 16, the method of any of claims 1-15, wherein the surface of the non-metallic component is a 3D surface.

In an Example 17, the method of Example 16, further comprising bonding or adhering a gold layer over the metallized tie layer prior to joining the metallized tie layer with the mated metallic surface of the second component using metal to metal joining techniques.

In an Example 18, the method of Example 1, wherein the metal to metal joining techniques include reflow of tin based solder attached to both surfaces.

In an Example 19, the method of Example 1, wherein the non-metallic component is a resin plastic injection molded component, and the surface of the second component is a metallic 3D curved surface.

In an Example 20, the method of Example 1, wherein the non-metallic component has a 3D curved surface, and the surface of the second component is a metallic 3D curved surface.

In an Example 21, the method of Example 1, wherein the metal to metal joining techniques include reflow of tin based solder attached to the metallized tie layer.

In an Example 22, the method of Example 21, wherein the solder is bonded to the non-metallic component with a solderable metal.

In an Example 23, the method of Example 22, wherein the solderable metal includes one or more of Cu, Au, Ag, Ni, Ru, Cd, Sn, Rd, Brass and Pb.

In an Example 24, the method of Example 22, wherein the solderable metal is cohesively bonded to the non-metallic component by the metallized tie layer.

In an Example 25, the method of Example 22, wherein the solderable metal is chosen from one that forms an intermetallic without fully dissolving into the solder.

In an Example 26, the method of Example 22, wherein the solderable metal is chosen from one that can be electroplated to the metallic surface of the second component.

In an Example 27, the method of Example 1, wherein the second component is a metal component.

In an Example 28, the method of Example 1, wherein the second component is a second non-metallic component, wherein the mated metallic surface of the second component includes a second metallized tie layer.

In an Example 29, the method of Example 28, wherein the second non-metallic component is one of a group consisting of: a polymeric component, a ceramic component, a ceramic-polymer composite, and a resin plastic injection molded component.

Although the disclosed techniques have been described with reference to various examples, those skilled in the art will recognize that changes can be made in form and detail without departing from the spirit and scope of this disclosure.

What is claimed is:

1. A method of manufacture comprising:
forming a metallized tie layer on a surface of a non-metallic component;
positioning the surface of the non-metallic component to mate with a metallic surface of a second component; and
joining the metallized tie layer with the mated metallic surface of the second component using metal to metal joining techniques.

2. The method of claim 1, wherein the non-metallic component is one of a group consisting of:
a polymeric component;
a ceramic component;
a ceramic-polymer composite component; and
a resin plastic injection molded component.

3. The method of claim 1, wherein the metal to metal joining techniques include compression fusion welding.

4. The method of claim 3, wherein the surfaces of the non-metallic component and the metallic surface of the second component are gold plated, wherein the compression fusion welding is made by contacting the two gold plated surfaces and applying an energy source.

5. The method of claim 4, wherein the energy source is ultrasonic or megasonic in nature.

6. The method of claim 4, wherein the gold is held to the surface of the non-metallic component by another metal forming the metallized tie layer.

7. The method of claim 1, wherein forming a metallized tie layer includes at least one of:
electroplating;
electroless plating;
vacuum deposition;
sputtering of a metal including one or more of Ti, Cr, Ta, Ru, NiChrome and NiV; and
vapor deposition.

8. The method of claim 1 further comprising modifying the surface of the non-metallic component by at least one of:
an ion source containing oxygen, or argon or both prior to forming the metallized tie layer on the surface of the non-metallic component; and
an plasma source containing oxygen, or argon or both prior to forming the metallized tie layer on the surface of the non-metallic component.

9. The method of claim 1, wherein the surface of the non-metallic component is a 3D surface.

10. The method of claim 9, further comprising bonding or adhering a gold layer over the metallized tie layer prior to joining the metallized tie layer with the mated metallic surface of the second component using metal to metal joining techniques.

11. The method of claim 9, wherein the non-metallic component is a resin plastic injection molded component.

12. The method of claim 1, wherein the metal to metal joining techniques include at least one of:
reflow of tin based solder attached to both surfaces, and
reflow of tin based solder attached to the metallized tie layer.

13. The method of claim 12, wherein the solder is bonded to the non-metallic component with a solderable metal.

14. The method of claim 13, wherein the solderable metal includes one or more of Cu, Au, Ag, Ni, Ru, Cd, Sn, Rd, Brass and Pb.

15. The method of claim 13, wherein the solderable metal is cohesively bonded to the non-metallic component by the metallized tie layer.

16. The method of claim 13, wherein the solderable metal is chosen from one that forms an intermetallic without fully dissolving into the solder.

17. The method of claim 13, wherein the solderable metal is chosen from one that can be electroplated to the metallic surface of the second component.

18. The method of claim 1, wherein the second component is a metal component.

19. The method of claim 1, wherein the second component is a second non-metallic component, wherein the mated metallic surface of the second component includes a second metallized tie layer.

20. The method of claim 19, wherein the second non-metallic component is one of a group consisting of:
a polymeric component;
a ceramic component;
a ceramic-polymer composite component; and
a resin plastic injection molded component.
